(19) United States
(12) Patent Application Publication
(10) Pub. No.: US 2018/0338049 A1
(43) Pub. Date: Nov. 22, 2018

(54) IMAGE PROCESSING APPARATUS PERFORMING IMAGE RECOVERY PROCESSING, IMAGING APPARATUS, IMAGE PROCESSING METHOD, AND STORAGE MEDIUM

(71) Applicant: CANON KABUSHIKI KAISHA, Tokyo (JP)

(72) Inventor: Fumihito Wachi, Tokyo (JP)

(21) Appl. No.: 15/947,633

(22) Filed: Apr. 6, 2018

(30) Foreign Application Priority Data
May 17, 2017 (JP) 2017-098402

(51) Int. Cl. H04N 1/00; H01L 27/146; H04N 5/374; H04N 5/225

(52) U.S. Cl. CPC H04N 1/00084; H01L 27/14645; H01L 27/14625; H04N 5/2254; H04N 5/374

(57) ABSTRACT

An image processing apparatus is provided which can perform image recovery processing with high accuracy. The image processing apparatus acquires first image data from a first imaging element configured to receive a first light flux as a result of a division of light performed by an optical element, acquires second image data from a second imaging element configured to receive a second light flux as a result of the division of the light performed by the optical element, performs image recovery processing on the first image data by using a first image recovery filter generated based on information relating to an optical transfer function of the first light flux, and performs image recovery processing on the second image data by using a second image recovery filter generated based on information relating to an optical transfer function of the second light flux.

### BACKGROUND OF THE INVENTION

### Field of the Invention

The present disclosure relates to an image processing apparatus which may perform image recovery processing.

### Description of the Related Art

In recent years, imaging apparatuses such as a digital still camera and a digital camcorder have been widely spread which may include an imaging element such as a CCD image sensor and a CMOS image sensor. In such an imaging apparatus, to divide the light flux, a half mirror may be arranged on an optical path where a light flux (imaging light flux) from an imaging optical system passes through. The half mirror is an optical element configured to divide an imaging light flux without substantially changing its spectral transmittance. When such a half mirror is used, the transmitted light and the reflected light may have substantially equal spectral transmittances in their visible light wavelength regions.

Japanese Patent Laid-Open No. 2013-172304 discloses an imaging apparatus including an optical system configured to divide a captured light flux by using a half mirror, wherein image data are corrected by using a transfer function defining an image degradation at least due to an aberration of the half mirror. Japanese Patent Laid-Open No. 2014-132790 discloses an imaging apparatus including an optical system configured to divide a captured light flux by using a half mirror, wherein a degradation due to internal reflection of the half mirror is corrected.

### SUMMARY OF THE INVENTION

The imaging apparatus disclosed in Japanese Patent Laid-Open No. 2013-172304 does not have a device for capturing an image of reflected light and is not capable of simultaneously capturing images by using two imaging elements. With respect to the optical transfer function of the half mirror therein, transmitted light can be corrected, but reflected light cannot be corrected. Also, how an optical transfer function is to be corrected to reflect it on a captured image is not clear. Further, because the optical transfer function for the imaging optical system is not corrected, a captured image cannot be sufficiently corrected.

The imaging apparatus disclosed in Japanese Patent Laid-Open No. 2014-132790 can correct optically undesirable light (ghost) generated by internal reflection from the half mirror therein but does not correct an aberration generated by a lens or the half mirror. The imaging apparatuses disclosed in Japanese Patent Laid-Open No. 2013-172304 and Japanese Patent Laid-Open No. 2014-132790 do not have a configuration for performing highly accurate image recovery processing on an image acquired through the half mirror.

In consideration of the above-noted issues, an image processing apparatus according to an aspect of the present disclosure includes at least one processor, and a memory including instructions that, when executed by the at least one processor, cause the at least one processor to acquire first image data from a first imaging element configured to receive a first light flux as a result of a division of light performed by an optical element, acquire second image data from a second imaging element configured to receive a second light flux as a result of the division of the light performed by the optical element, perform image recovery processing on the first image data by using a first image recovery filter generated based on information relating to an optical transfer function of the first light flux, and perform image recovery processing on the second image data by using a second image recovery filter generated based on information relating to an optical transfer function of the second light flux.

The other objects and features of the present disclosure will be described with reference to the following embodiments.

Further features of the present invention will become apparent from the following description of exemplary embodiments with reference to the attached drawings.

### BRIEF DESCRIPTION OF THE DRAWINGS

FIG. 1 is a block diagram illustrating an imaging apparatus according to an embodiment.

FIG. 2 is a schematic diagram illustrating a reflecting surface of a half mirror according to an embodiment.

FIG. 3 is a schematic diagram illustrating a transmission wave surface of a half mirror according to an embodiment.

FIG. 4 is a flowchart illustrating image recovery processing according to a first embodiment.

FIG. 5 is a flowchart illustrating image recovery processing according to a second embodiment.

FIG. 6 is an explanatory diagram illustrating a refracting angle of transmitted light through a half mirror according to an embodiment.

### DESCRIPTION OF THE EMBODIMENTS

Embodiments of the present disclosure will be described in detail with reference to drawings.

First, image recovery processing according to an embodiment will generally be described. An image captured by an imaging apparatus such as a digital camera contains a blurring component caused by an aberration in an imaging optical system. Thus, the image captured by the imaging apparatus is not a little degraded compared with an ideal image.

A blurring component of such an image may be caused by aberrations such as a spherical aberration, a comatic aberration, a curvature of image field, and astigmatism in the imaging optical system. An image blurring component due to such an aberration is caused by a light flux emitted from one point of an object focused not to one point but in a spread manner on an imaging plane without aberrations and free of influence from diffraction. It is optically called a point spread function (PSF) but is called a blurring component according to this embodiment. Though a defocused image is also called a blurred image, the blurring of an image according to this embodiment corresponds to blurring due to an influence of an aberration in the imaging optical system even when the image is focused. Color fringing of a polychrome image due to an axial chromatic aberration in an imaging optical system, a spherical aberration of color, or a comatic aberration of color may be a different type of blurring based on the wavelength of light. Color deviation in a meridional direction of color caused by a magnification chromatic aberration in an optical system may be a displacement or a phase shift due to a difference in imaging magnification between wavelengths of light.

An optical transfer function (OTF) obtained by performing a Fourier transform on the PSF is frequency component information regarding an aberration and is represented by a complex number. The absolute value or amplitude component of the OTF is called a Modulation Transfer Function (MTF), and a phase component thereof is called a Phase Transfer Function (PTF). The MTF and PTF are frequency characteristics of an amplitude component and a phase component of an image degradation due to an aberration. According to this embodiment, the phase component PTF is expressed as a phase angle by the following Expression (1).

PTF=tan⁻¹(Im(OTF)/Re(OTF)) (1)

In Expression (1), Re(OTF) and Im(OTF) represent a real part and an imaginary part, respectively, of an OTF. An OTF of an imaging optical system degrades both of an amplitude component and a phase component of an image. Therefore, the degraded image has points of an object blurred asymmetrically like one due to a comatic aberration.

A magnification chromatic aberration is caused by acquiring an image-forming position deviated due to a difference in imaging magnification between wavelengths of light as an RGB color component, for example, based on spectral characteristics of an imaging apparatus. Therefore, an image spread occurs due to not only differences in image-forming positions between RGB but also differences in image-forming positions or phase deviations between wavelengths within each color component. A color deviation will be described as a synonym for a magnification chromatic aberration unless otherwise specified though a magnification chromatic aberration is not precisely a simple color deviation with a parallel shift.

A method has been known which corrects a degraded amplitude (MTF) and a degraded phase (PTF) by using information regarding OTFs of all optical members placed not only in an imaging optical system but also on an imaging optical path. This method is called an image recovery or an image reconstruction. In the following description, processing for correcting a degradation of an image by using information regarding OTFs of all optical members placed not only in an imaging optical system but also on an imaging optical path will be called image recovery processing.

Here, when a degraded image is g(x,y), an original image is f(x,y), and a point image distribution function PSF acquired by performing a reverse Fourier transform on an optical transfer function OTF is h(x,y), the following Expression (2) is satisfied.

g(x,y)=h(x,y)*f(x,y) (2)

In Expression (2), * represents a convolution, and (x,y) represents coordinates on an image.

Performing a Fourier transform on Expression (2) for conversion to a display style on a frequency surface results in a product form for each frequency as in the following Expression (3).

G(u,v)=H(u,v)*F(u,v) (3)

In Expression (3), H is a result of a Fourier transform performed on a PSF and represents an OTF. (u,v) represents coordinates on a two-dimensional frequency surface, that is, a frequency.

In order to acquire an original image from a captured degraded image, both sides of Expression (3) may be divided by H as in the following Expression (4).

G(u,v)/H(u,v)=F(u,v) (4)

By performing a reverse Fourier transform on F(u,v) in Expression (4) for conversion back to a real surface, an original image f(x,y) is acquired as a recovery image.

Here, when R is acquired by performing a reverse Fourier transform on 1/H in Expression (4), an original image can be acquired by performing a convolution process on an image on a real surface as in the following Expression (5).

g(x,y)*R(x,y)=f(x,y) (5)

R(x,y) in Expression (5) will be called an image recovery filter. An actual image has a noise component. By using the image recovery filter generated by using the inverse number of an OTF as described above, the degraded image and the noise component are both amplified. As a result, a satisfactory image cannot be generally acquired. In order to address this matter, a method has been known which can suppress the recovery rate of a high frequency side of an image based on an intensity ratio between an image signal and a noise signal like a Wiener filter, for example. A degradation of a color fringing component of an image can be corrected by correcting a blurring component as described above, for example, to acquire an even blurring amount between components of the image. Because the OTF changes in accordance with photographing conditions (image-capturing conditions) such as a zoom position and an aperture diameter, the image recovery filter to be used for the image recovery processing may be changed based on the changes of the conditions.

Image recovery processing with high accuracy by using an imaging apparatus having a half mirror on an imaging optical path therein may be performed in consideration of aberrations relating to reflected light from and transmitted light through the half mirror. In other words, an aberration relating to reflected light from the half mirror includes an aberration caused depending on the profile irregularity of the reflecting surface of the half mirror. An aberration relating to transmitted light through the half mirror includes a spherical aberration, a comatic aberration, astigmatism, and an aberration due to a manufacturing error of the half mirror. The image recovery filter may be generated in consideration of an aberration of the imaging optical system.

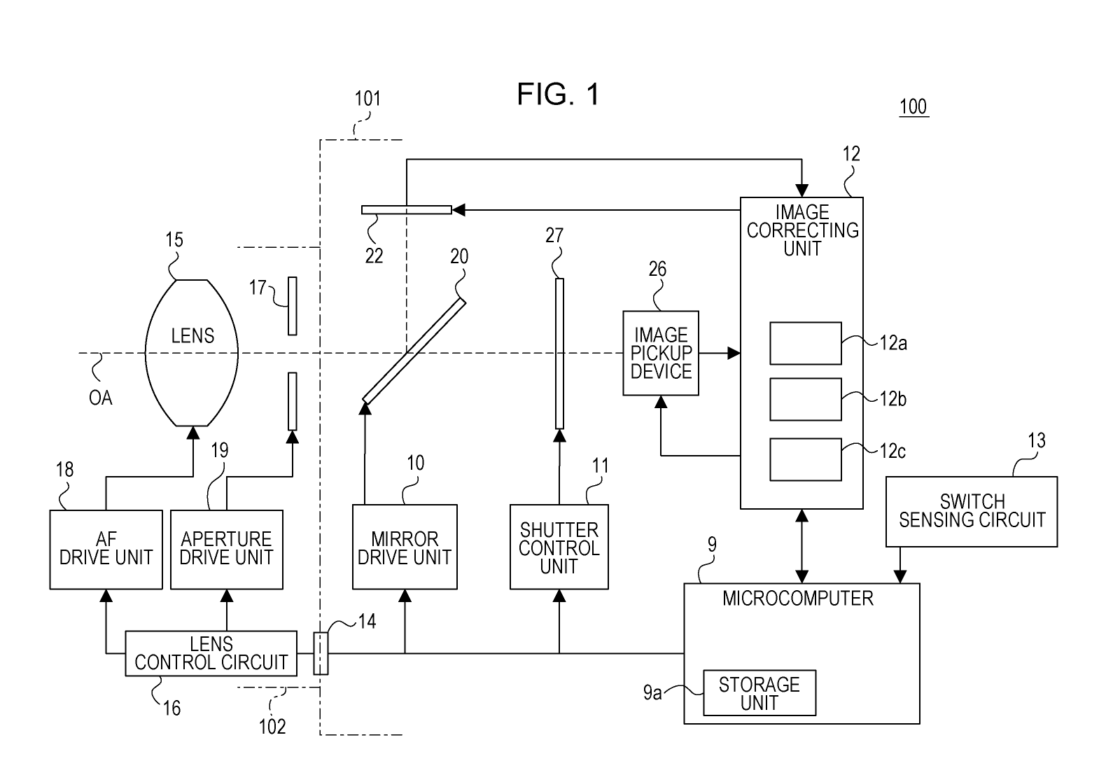

Next, with reference to FIG. 1, a configuration of an imaging apparatus according to this embodiment will be described. FIG. 1 is a block diagram illustrating an imaging apparatus 100. The imaging apparatus 100 includes a camera main body (imaging apparatus main body) 101 and a replaceable lens (lens unit) 102 detachably attached to the camera main body 101. However, this embodiment is not limited thereto but is also applicable to an imaging apparatus including an imaging apparatus main body and a lens unit which are integrally provided.

The imaging apparatus 100 according to this embodiment includes a first imaging element 22 and a second imaging element 26 and is configured to divide a light flux obtained through a lens 15 into reflected light from and transmitted light through a half mirror (optical element) 20 and to cause the reflected light and transmitted light to enter to the two imaging elements. In other words, the first imaging element 22 is configured to receive a first light flux as a result of a division of light by the half mirror 20 and output first image data. The second imaging element 26 is configured to receive a second light flux as a result of the division of the light by the half mirror 20 and output second image data. According to this embodiment, the first light flux is light reflected from the half mirror 20 via the lens 15, and the second light flux is light transmitted through the half mirror 20 via the lens 15. This configuration enables to simultaneously capture images (such as a moving image and a still image).

In the imaging apparatus 100, a microcomputer (MPU) 9 is configured to control an operation to be performed by the imaging apparatus 100 by instructing a component of the imaging apparatus 100 to execute one of various processes. A memory 9a internally provided in the MPU 9 is configured to store information regarding a plurality of optical transfer functions (optical aberration transfer functions) generated based on aberrations (optical aberrations) of an imaging optical system. The memory 9a is further configured to store a plurality of image correction information pieces calculated based on the plurality of optical transfer functions, set values relating to image-capturing, and data such as parameters for operations to be performed by the imaging apparatus 100.

The microcomputer 9 is connected to a mirror drive mechanism 10, a shutter drive mechanism 11, an image correcting circuit 12, and a switch sensing circuit 13. These components (units) are configured to perform communications, transmit information, and perform operations under control of the microcomputer 9. The microcomputer 9 communicates with a lens control circuit 16 provided in the replaceable lens (lens unit) 102 through a mount contact 14. The lens control circuit 16 may communicate with the microcomputer 9 to drive the lens (imaging optical system) 15 and an aperture 17 in the lens unit 102 through an AF drive mechanism 18 and an aperture drive mechanism 19 to acquire drive information regarding the lens 15 and the aperture 17.

On the back side (image side) of the lens 15, the imaging apparatus 100 internally contains the first imaging element 22, the second imaging element 26, the half mirror 20, and a shutter 27. The half mirror 20 is arranged in a light flux (imaging light flux) of an object image (optical image) emitted from the lens 15. The half mirror 20 is driven by the mirror drive mechanism 10 based on a command from the microcomputer 9. The half mirror 20 folds back upward a substantial half amount of a light flux transmitted from an object through the lens 15 to form an object image (optical image) on the first imaging element 22. According to this embodiment, the first imaging element 22 may be a CMOS sensor that is a two-dimensional imaging device for capturing a moving image and is configured to capture frames by using an electronic shutter.

The shutter 27 has a shield member which can move toward and away from an optical path (imaging light flux) to the imaging element 26. According to this embodiment, the shutter 27 may be a mechanical focal plane shutter. The shutter 27 has front blades and rear blades, for example. The front blades are configured to be retracted from an optical path of the object light flux (imaging light flux) to start exposure in response to a release signal for imaging, and the rear blades are configured to shield the object light flux at a predetermined time after the front blades start running. The shutter 27 is driven by the shutter drive mechanism 11 based on a command from the microcomputer 9. According to this embodiment, the second imaging element 26 may be a CMOS sensor that is a two-dimensional imaging device and is configured to guide or shield an object light flux to the second imaging element 26 by using the shutter 27.

According to this embodiment, the image correcting circuit 12 may be an image processing apparatus configured to perform image recovery processing. The image correcting circuit 12 has a memory 12a, a generating circuit 12b, and a correcting circuit 12c. The memory 12a is configured to receive first image data from the first imaging element 22 which receives a first light flux (reflected light) and receive second image data from the second imaging element 26 which receives a second light flux (transmitted light) and store the first and second image data. The generating circuit 12b is configured to generate a first image recovery filter based on information (first point spread function) regarding an optical transfer function of the first light flux and generate a second image recovery filter based on information (second point spread function) regarding an optical transfer function of the second light flux. The correcting circuit 12c is configured to perform image recovery processing on the first image data by using the first image recovery filter and to perform image recovery processing on the second image data by using the second image recovery filter. In other words, the correcting circuit 12c may perform image recovery processing on the first image data and the second image data so that aberrations contained in the first image data and the second image data can be reduced. While the generating circuit 12b and the correcting circuit 12c are described as separate circuits for easy understanding of the description, they may be configured by one common circuit. Alternatively, the image correcting circuit 12 and the microcomputer 9 may be configured as an integrated processor.

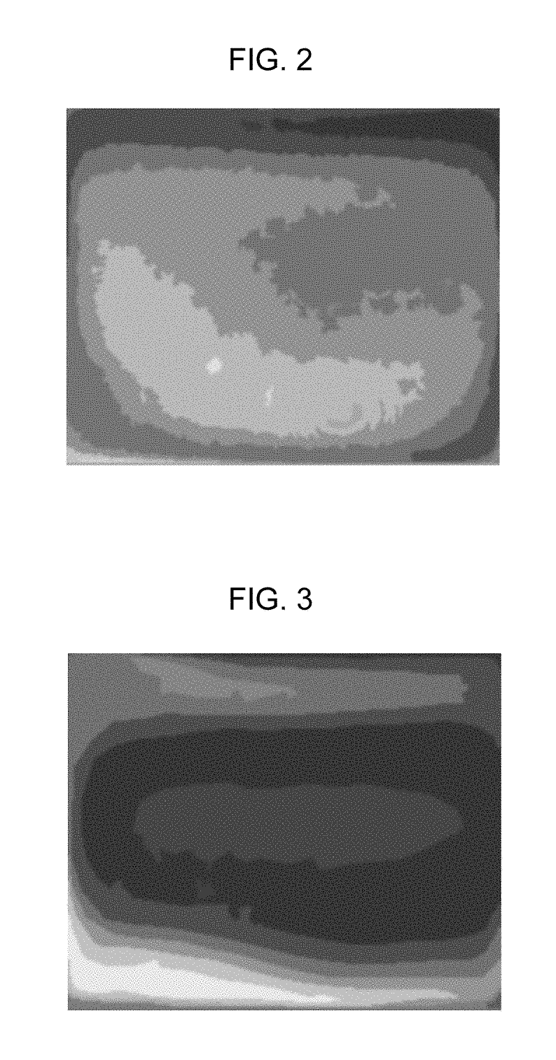

Next, with reference to FIG. 2, the profile irregularity of the reflecting surface of the half mirror 20 which guides an object light flux to the first imaging element 22 will be described. FIG. 2 is a schematic diagram of the reflecting surface of the half mirror 20 and illustrates interference fringes of the reflecting surface obtained by an interferometer. The surface shape (profile irregularity) of the half mirror 20 can be acquired based on the interference fringes of the reflecting surface of the half mirror 20, and an aberration (optical aberration) occurring in the light flux reflected by the reflecting surface can be acquired. Based on the acquired aberration, a PSF (point spread function) for correcting the aberration can be calculated. Both of a PSF including information regarding the optical aberration of the imaging optical system and a PSF including information regarding the optical aberration of the reflecting surface of the half mirror 20 may be acquired and may be convoluted. Thus, a PSF can be acquired which includes both of the optical aberration of the imaging optical system and the optical aberration due to the reflecting surface of the half mirror. Based on the acquired PSF, an image recovery filter for an image (captured image) captured by the first imaging element 22 can be generated.

Next, with reference to FIG. 3, a transmission wave surface of the half mirror 20 which guides an object light flux to the second imaging element 26 will be described. FIG. 3 is a schematic diagram of the transmission wave surface of the half mirror 20 and illustrates interference fringes of the transmission wave surface of the half mirror 20 obtained by an interferometer. The wave surface shape of the light flux transmitting through the half mirror 20 can be acquired based on the interference fringes of the transmission wave surface, and an aberration (optical aberration) occurring in the light flux transmitting through the half mirror 20 can be acquired. Based on the acquired aberration, a PSF for correcting the aberration can be calculated. Both of a PSF including information regarding the optical aberration of the imaging optical system and a PSF including information regarding the optical aberration occurring in the transmitted light through the half mirror 20 may be acquired and may be convoluted. Thus, a PSF including both of the optical aberration of the imaging optical system and the optical aberration occurring in the transmitted light through the half mirror can be acquired. Based on the acquired PSF, an image recovery filter for an image (captured image) captured by the second imaging element 26 can be generated.

Having described a case where the profile irregularity of the reflecting surface of the half mirror 20 is measured by an interferometer according to this embodiment, the method for measuring a profile irregularity is not limited to methods using an interferometer. For example, a contact type measuring instrument may be used to measure the profile irregularity and thus measure the surface shape to acquire an optical aberration. Having described that, according to this embodiment, the shutter 27 being a mechanical shutter is arranged before the second imaging element 26 configured to capture an image of transmitted light from the half mirror 20, the mechanical shutter may be arranged before the first imaging element 22. For example, the mechanical shutter arranged between the half mirror 20 and the imaging optical system can have one mechanical shutter mechanism which provides a mechanical shutter function to both of the first imaging element 22 and the second imaging element 26. Having described that, according to this embodiment, the first imaging element 22 handles a moving image and that the second imaging element 26 handles a still image as their objectives, embodiments of the present disclosure are not limited thereto. The first imaging element 22 and the second imaging element 26 may exchange their roles with each other. Alternatively, both of the first imaging element 22 and the second imaging element 26 may capture still images or may capture moving images. While the first imaging element 22 and the second imaging element 26 have an equal size according to this embodiment, embodiments of the present disclosure are not limited thereto. For example, a reduced-size optical system may be arranged between the half mirror 20 and the first imaging element 22 or the second imaging element 26 so that the sizes of the first imaging element 22 and the second imaging element 26 can be arbitrarily changed.

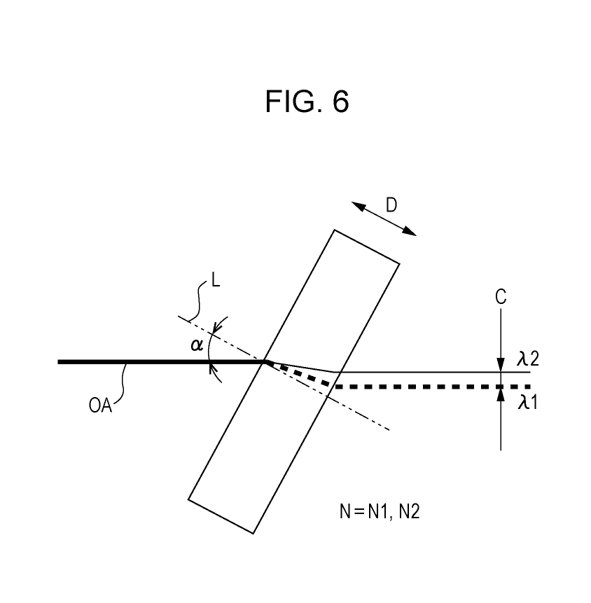

Next, with reference to FIG. 6, an offset of an image plane of transmitted light through the half mirror 20 will be described. FIG. 6 is an explanatory diagram illustrating a refracting angle of transmitted light through the half mirror 20. In accordance with the refractive index of the half mirror 20, the angle formed by the half mirror 20 and an optical axis OA, and the wavelength of the light beam transmitting through the half mirror 20, an image of transmitted light having the wavelength through the imaging optical system may be offset from a line connecting from an object to the center of the optical axis of the lens.

It is assumed here that light has wavelengths λ1 and λ2. The half mirror 20 is made of a material having a refractive index N1 against the wavelength λ1 and a refractive index N2 against the wavelength λ2. An angle α is formed by the half mirror 20 (or a normal L of the half mirror 20) and the optical axis OA of the imaging optical system. The half mirror 20 has a thickness D and has an image plane having a displacement amount C. In this case, the following Expressions (6-1), (6-2), and (6-3) are satisfied.

α1=arcsin(sin α/N1) (6-1)

α2=arcsin(sin α/N2) (6-2)

C=D(tan α2−tan α1)cos α (6-3)

Because the image plane is defocused for each wavelength, image planes may be superimposed with the edges out of line to generate a final output image in consideration of spectral characteristics of color filters. Data regarding PSFs may be calculated in advance and may be stored in the memory 9a in a database form. Corresponding data thereof may be read out for image capturing. For a reduced volume of data, data regarding a PSF may be stored as a wave surface data. Image processing methods according to embodiments will be described in detail below.

### First Embodiment

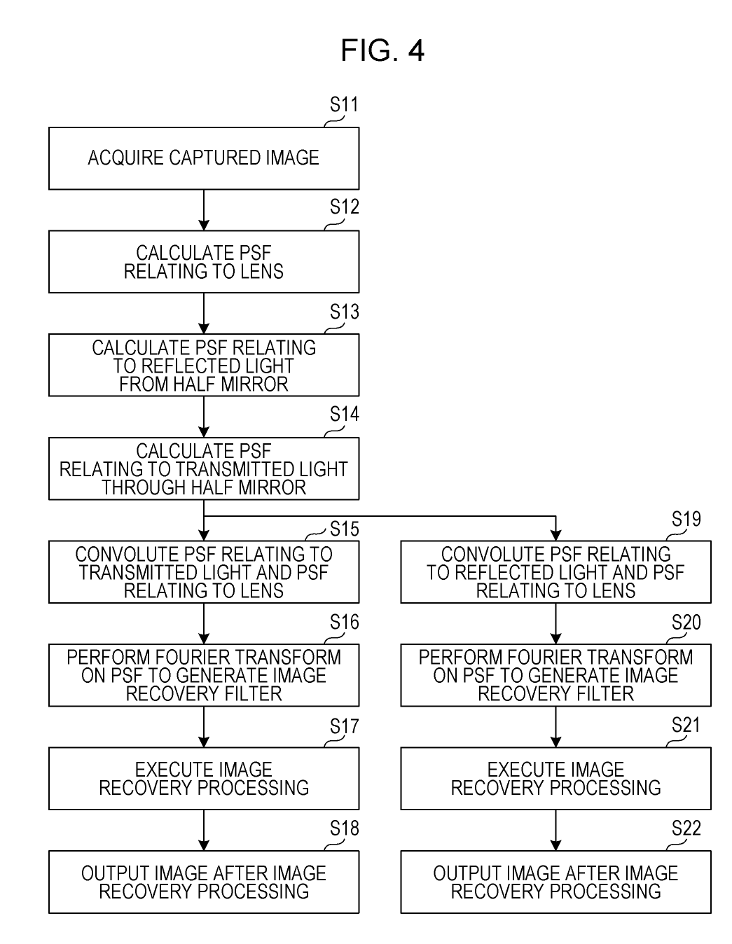

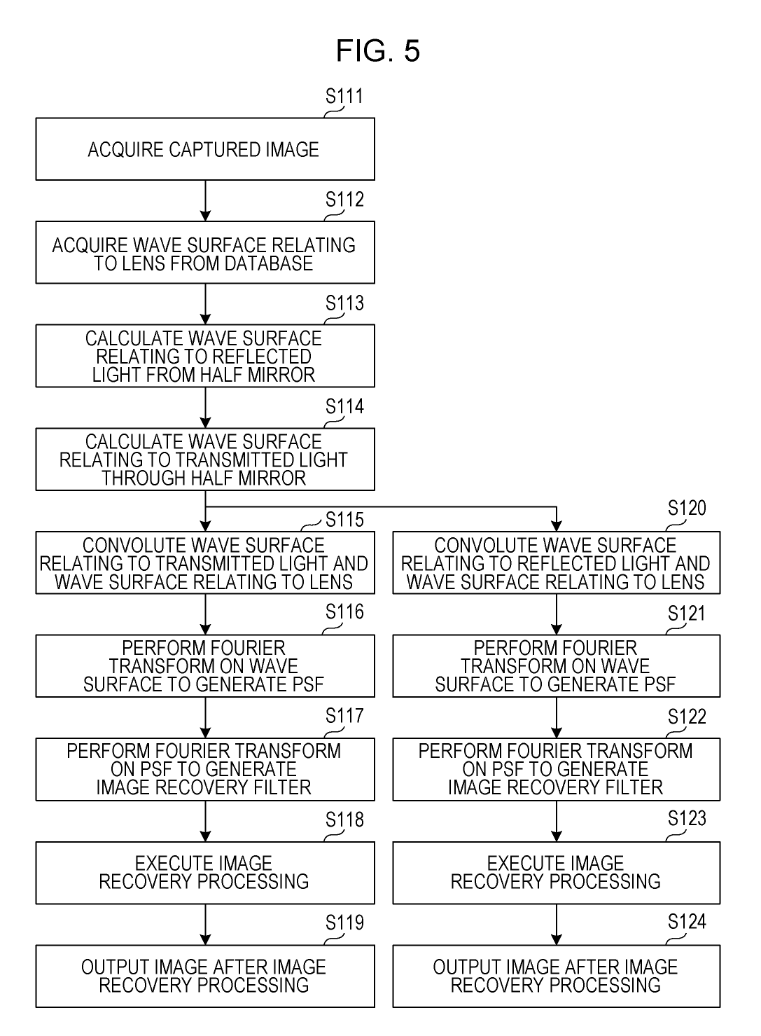

First, an image processing method according to a first embodiment of the present disclosure will be described with reference to FIG. 4. FIG. 4 is a flowchart illustrating an image processing method (image-capturing operation) according to this embodiment. Steps in FIG. 4 are mainly to be executed by the components of the image correcting circuit 12 based on commands from the microcomputer 9.

When the imaging apparatus 100 starts an image-capturing operation, the image correcting circuit 12 (memory 12a) in step S11 first acquires captured images from the first imaging element 22 and the second imaging element 26. Next, in step S12, the image correcting circuit 12 (generating circuit 12b) calculates a PSF relating to the lens 15 or the imaging optical system. In this case, information regarding a manufacturing error of the lens 15 may be included in the PSF for further improved accuracy of the image recovery processing.

Next, in step S13, the image correcting circuit 12 (generating circuit 12b) calculates a PSF relating to reflected light from the half mirror 20. The image correcting circuit 12 may calculate a PSF in consideration of the profile irregularity of the reflecting surface of the half mirror 20. In other words, the generating circuit 12b generates a PSF relating to reflected light based on an optical aberration depending on the shape (profile irregularity) of the reflecting surface of the half mirror 20. Next, in step S14, the image correcting circuit 12 (generating circuit 12b) calculates a PSF relating to transmitted light through the half mirror 20. In other words, the image correcting circuit 12 (generating circuit 12b) generates a PSF relating to the transmitted light based on an optical aberration depending on the transmission wave surface of the half mirror 20. In a case where the half mirror 20 does not include a manufacturing error, a light flux (transmitted light) transmitting through the half mirror 20 has an optical aberration. In a case where the half mirror 20 includes a manufacturing error, an optical aberration due to the manufacturing error occurs. Therefore, the image correcting circuit 12 calculates a PSF according to the aberration.

Next in step S15, the image correcting circuit 12 (generating circuit 12b) convolutes (convolution-integrates) the PSF relating to the transmitted light through the half mirror 20 calculated in step S14 and the PSF relating to the lens 15 calculated in step S12. Next in step S16, the image correcting circuit 12 (generating circuit 12b) performs Fourier transform on the PSF calculated in step S15 to generate an image recovery filter. Next in step S17, the image correcting circuit 12 (correcting circuit 12c) uses the image recovery filter generated in step S16 to perform image recovery processing on the captured image acquired from the second imaging element 26. Next in step S18, the image correcting circuit 12 (correcting circuit 12c) outputs the image generated by executing the image recovery processing in step S17 as an image captured by the second imaging element 26.

In step S19, the image correcting circuit 12 (generating circuit 12b) convolutes (convolution-integrates) the PSF relating to the reflected light through the half mirror 20 calculated in step S13 and the PSF relating to the lens 15 calculated in step S12. Next in step S20, the image correcting circuit 12 (generating circuit 12b) performs a Fourier transform on the PSF calculated in step S19 to generate an image recovery filter. Next in step S21, the image correcting circuit 12 (correcting circuit 12c) uses the image recovery filter generated in step S20 to perform image recovery processing on the captured image acquire from the first imaging element 22. Next in step S22, the image correcting circuit 12 (correcting circuit 12c) outputs the image generated by executing the image recovery processing in step S21 as an image captured by the first imaging element 22.

According to this embodiment, each of the PSF (PSF relating to the transmitted light) generated in step S15 and the PSF (PSF relating to the reflected light) generated in step S19 may include the PSF (PSF relating to the lens 15) acquired in step S12. The image recovery processing according to this embodiment, which is described with reference to FIG. 4, is also applicable to both of a still image and a moving image.

### Second Embodiment

Next, with reference to FIG. 5, an image processing method according to a second embodiment of the present disclosure will be described. FIG. 5 is a flowchart illustrating an image processing method (image-capturing operation) according to this embodiment. Steps in FIG. 5 are mainly to be executed by the components of the image correcting circuit 12 based on commands from the microcomputer 9.

When the imaging apparatus 100 starts an image-capturing operation, the image correcting circuit 12 in step S111 first acquires captured images from the first imaging element 22 and the second imaging element 26. Next in step S112, the image correcting circuit 12 reads out information (wave surface data) relating to a wave surface of the lens 15 or the imaging optical system from a database stored in the memory 9a. In this case, information regarding a manufacturing error of the lens 15 may be included in the wave surface data for further improved accuracy of the image recovery processing.

Next in step S113, the image correcting circuit 12 (memory 12a) calculates (acquires) wave surface data relating to reflected light from the half mirror 20 (information regarding the wave surface of the reflected light). The image correcting circuit 12 may calculate wave surface data in consideration of the profile irregularity (shape) of the reflecting surface of the half mirror 20. Next in step S114, the image correcting circuit 12 (memory 12a) calculates (acquires) wave surface data relating to transmitted light through the half mirror 20 (information regarding the wave surface of the transmitted light). In a case where the half mirror 20 does not include a manufacturing error, a light flux (transmitted light) transmitting through the half mirror 20 has an optical aberration. In addition, in a case where the half mirror 20 includes a manufacturing error, an optical aberration due to the manufacturing error occurs. Therefore, the image correcting circuit 12 calculates wave surface data according to the aberration.

Next in step S115, the image correcting circuit 12 convolutes (convolution-integrates) the wave surface data relating to the transmitted light through the half mirror 20 calculated in step S114 and the wave surface data relating to the lens 15 read out in step S112. Next in step S116, the image correcting circuit 12 (generating circuit 12b) performs a Fourier transform on the wave surface data calculated in step S115 to generate a PSF. Next in step S117, the image correcting circuit 12 (generating circuit 12b) performs a Fourier transform on the PSF generated in step S116 to generate an image recovery filter. Next in step S118, the image correcting circuit 12 (correcting circuit 12c) uses the image recovery filter generated in step S117 to perform image recovery processing on the captured image acquired from the second imaging element 26. Next in step S119, the image correcting circuit 12 outputs the image generated by executing the image recovery processing in step S118 as an image captured by the second imaging element 26.

In step S120, the image correcting circuit 12 convolutes (convolution-integrates) the wave surface data relating to the reflected light through the half mirror 20 calculated in step S114 and the wave surface data relating to the lens 15 read out from the database in step S112. Next in step S121, the image correcting circuit 12 (generating circuit 12b) performs a Fourier transform on the wave surface data calculated in step S120 to generate a PSF. Next in step S122, the image correcting circuit 12 (generating circuit 12b) performs a Fourier transform on the PSF generated in step S121 to generate an image recovery filter.

Next in step S123, the image correcting circuit 12 (correcting circuit 12c) uses the image recovery filter generated in step S122 to perform image recovery processing on the captured image acquired from the second imaging element 26. Next in step S124, the image correcting circuit 12 outputs the image generated by executing the image recovery processing in step S123 as an image captured by the second imaging element 26. It should be noted that the image recovery processing according to this embodiment described with reference to FIG. 5 is applicable to both of a still image and a moving image.

Having described that, according to the first and second embodiments, the generating circuit 12b in the image correcting circuit 12 is configured to generate an image recovery filter, embodiments of the present disclosure are not limited thereto. Image recovery filters according to PSFs of a plurality of image-capturing conditions may be prestored in a memory, or an image recovery filter according to a PSF of an image-capturing condition may be acquired from an external unit through a communication. Particularly, an imaging apparatus integrally having an imaging apparatus main body and a lens unit may employ fewer image recovery filters than an imaging apparatus having a replaceable lens unit. Though image recovery filters having larger volumes of data may employ a large capacity memory for storage, the processing time for generating an image recovery filter can be reduced.

### Others Embodiments

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2017-098402 filed May 17, 2017, which is hereby incorporated by reference herein in its entirety.

What is claimed is:

1. An image processing apparatus comprising:
at least one processor; and
a memory including instructions that, when executed by the at least one processor, cause the at least one processor to:
acquire first image data from a first imaging element configured to receive a first light flux as a result of a division of light by an optical element;
acquire second image data from a second imaging element configured to receive a second light flux as a result of the division of the light by the optical element;
perform image recovery processing on the first image data by using a first image recovery filter generated based on information relating to an optical transfer function of the first light flux; and
perform image recovery processing on the second image data by using a second image recovery filter generated based on information relating to an optical transfer function of the second light flux.

2. The image processing apparatus according to claim 1,
wherein the optical element is a half mirror;
wherein the first light flux is reflected light from the half mirror via an imaging optical system; and
wherein the second light flux is transmitted light through the half mirror via the imaging optical system.

3. The image processing apparatus according to claim 2,
wherein the instructions, when executed by the at least one processor, further cause the at least one processor to generate the information relating to the optical transfer function of the first light flux based on an aberration depending on a shape of a reflecting surface of the optical element.

4. The image processing apparatus according to claim 2,
wherein the instructions, when executed by the at least one processor, further cause the at least one processor to generate the information relating to the optical transfer function of the second light flux based on an aberration depending on a transmission wave surface of the optical element.

5. The image processing apparatus according to claim 1,
wherein the instructions, when executed by the at least one processor, further cause the at least one processor to:
acquire information relating to a wave surface of the first light flux and information relating to a wave surface of the second light flux;
generate information relating to an optical transfer function of the first light flux from the information relating to the wave surface of the first light flux; and
generate information relating to an optical transfer function of the second light flux from the information relating to the wave surface of the second light flux.

6. The image processing apparatus according to claim 1,
wherein the information relating to the optical transfer function of the first light flux is a first point spread function; and
wherein the information relating to the optical transfer function of the second light flux is a second point spread function.

7. The image processing apparatus according to claim 6,
wherein the instructions, when executed by the at least one processor, further cause the at least one processor to:
generate the first image recovery filter by performing a Fourier transform on the first point spread functional; and
generate the second image recovery filter by performing a Fourier transform on the second point spread function.

8. The image processing apparatus according to claim 1,
wherein the instructions, when executed by the at least one processor, further cause the at least one processor to perform the image recovery processing on the first image data and the second image data to reduce an aberration included in each of the first image data and the second image data.

9. The image processing apparatus according to claim 1,
wherein each of the information relating to the optical transfer function of the first light flux and the information relating to the optical transfer function of the second light flux includes information relating to an optical transfer function of the imaging optical system.

10. An imaging apparatus comprising:
a first imaging element configured to receive a first light flux as a result of a division of light performed by an optical element and outputs first image data;
a second imaging element configured to receive a second light flux as a result of the division of the light performed by the optical element and output second image data; and
an image correcting circuit configured to perform image recovery processing on the first image data by using a first image recovery filter generated based on information relating to an optical transfer function of the first light flux and perform image recovery processing on the second image data by using a second image recovery filter generated based on information relating to an optical transfer function of the second light flux.

11. An image processing method comprising:
acquiring first image data from a first imaging element configured to receive a first light flux as a result of a division of light performed by an optical element:
acquiring second image data from a second imaging element configured to receive a second light flux as a result of the division of the light performed by the optical element;
performing image recovery processing on the first image data by using a first image recovery filter generated based on information relating to an optical transfer function of the first light flux; and
performing image recovery processing on the second image data by using a second image recovery filter generated based on information relating to an optical transfer function of the second light flux.

12. A non-transitory computer-readable storage medium for storing an image processing program that enables a computer to:
acquire first image data from a first imaging element configured to receive a first light flux as a result of a division of light performed by an optical element;
acquire second image data from a second imaging element configured to receive a second light flux as a result of the division of the light performed by the optical element;
perform image recovery processing on the first image data by using a first image recovery filter generated based on information relating to an optical transfer function of the first light flux; and
perform image recovery processing on the second image data by using a second image recovery filter generated based on information relating to an optical transfer function of the second light flux.
